(19) United States
(12) Patent Application Publication
(10) Pub. No.: US 2025/0077723 A1
(43) Pub. Date: Mar. 6, 2025

(54) CORRECTING INACCURATE POSITIONS WITHIN STRUCTURAL REPRESENTATIONS

(71) Applicant: UNEARTHED LAND TECHNOLOGIES, LLC, Cocoa, FL (US)

(72) Inventors: Charles C. CARRINGTON, Cocoa, FL (US); Aaron Lane WESTRE, Minneapolis, MN (US)

(21) Appl. No.: 18/819,126

(22) Filed: Aug. 29, 2024

Related U.S. Application Data
(60) Provisional application No. 63/535,151, filed on Aug. 29, 2023.
(60) Provisional application No. 63/538,615, filed on Sep. 15, 2023.

(51) Int. Cl. G06F 30/13; G06F 30/27

(52) U.S. Cl. CPC G06F 30/13; G06F 30/27

(57) ABSTRACT

This disclosure provides systems, methods, and devices that improve positions of objects structural representations according to hierarchical positioning. In one aspect, a method is provided that includes receiving a first representation of a structure, determining a second representation of the structure by aligning positions of objects within the first representation according to a hierarchy, and outputting the second representation. The alignment process can prioritize objects based on hierarchical importance, with structural elements like grid objects being positioned before other objects like structural core objects, interior walls, and other elements. The techniques may also include training one or more models based on differences between initial and aligned representations. Additional aspects are also discussed.

### CROSS-REFERENCE TO RELATED APPLICATIONS

The present application claims priority to U.S. Provisional Patent Application Nos. 63/535,151, filed on Aug. 29, 2023, and 63/538,615, filed on Sep. 15, 2023. The disclosure of both are incorporated herein by reference for all purposes.

### BACKGROUND

Plans and other representations of structures may be prepared before, during, and/or after construction of the structures. In certain instances, these representations may have one or more inaccuracies or inconsistencies. For example, the positions of one or more objects may conflict with one another, or may not be physically possible.

### SUMMARY

The present disclosure presents new and innovative systems and methods for correcting inaccurate positions within structural representations. The present techniques relate to determining structural representations of buildings using machine learning models. An initial representation may be processed by a machine learning model to detect structural objects and initial positions. Positions for these objects may then be realigned according to a predetermined hierarchy, correcting any inaccuracies in the initial plans. The final output is an updated structural representation that can be used, e.g., for more accurate construction or architectural purposes.

A first aspect provides a method that includes receiving a first representation of a structure; determining a second representation of the structure by aligning positions of objects within the first representation according to a hierarchy; and outputting the second representation of the structure.

In a second aspect, in combination with one or more of the first aspect, the first representation is received from a machine learning model.

In a third aspect, in combination with one or more of the first aspect through the second aspect, the method further includes training the machine learning model based on differences between the first representation of the structure and the second representation of the structure.

In a fourth aspect, in combination with one or more of the first aspect through the third aspect, the method further includes determining indications of the objects and initial positions for the objects.

In a fifth aspect, in combination with the fourth aspect, the method further includes determining indications of the objects and the initial positions based on the first representation, plan documents for the structure, or a combination thereof.

In a sixth aspect, in combination with one or more of the fourth aspect through the fifth aspect, the indications of the objects and the initial positions are determined with a second machine learning model.

In a seventh aspect, in combination with one or more of the fourth aspect through the sixth aspect, the indications of the objects include (i) a type for the objects, (ii) dimensions for the objects, (iii) compositions of the objects, (iv) a source location within plan documents for the structure, or a combination thereof.

In an eighth aspect, in combination with one or more of the first aspect through the seventh aspect, the second representation of the structure is determined such that positions for objects located higher in the hierarchy take precedence over positions for objects located lower in the hierarchy.

In a ninth aspect, in combination with one or more of the first aspect through the eighth aspect, aligning the positions of the objects within the first representation includes determining, based on the objects and initial positions for the objects, first updated positions for the objects.

In a tenth aspect, in combination with the ninth aspect, the updated positions are determined with a third machine learning model.

In an eleventh aspect, in combination with one or more of the ninth aspect through the tenth aspect, determining the first updated positions includes determining a first subset of the first updated positions for a first subset of the objects by aligning objects of the first subset of objects across multiple floors of the structure.

In a twelfth aspect, in combination with the eleventh aspect, determining the first updated positions includes determining a third subset of the third updated positions for a third subset of the objects (i) based on the second subset of the second updated positions and (ii) by aligning objects of the third subset of the objects across multiple floors of the structure.

In a thirteenth aspect, in combination with one or more of the ninth aspect through the twelfth aspect, aligning the positions of the object further includes determining, based on the first updated positions for the objects, second updated positions for the objects.

In a fourteenth aspect, in combination with the thirteenth aspect, the method further includes determining that the second updated positions for the objects satisfy at least one condition; and using the second updated positions within the second representation of the structure.

In a fifteenth aspect, in combination with one or more of the first aspect through the fourteenth aspect, the hierarchy specifies that (1) positions for structural grid objects are determined, if present in the first representation, before (2) positions for structural core objects, if present in the first representation, which are determined before (3) exterior walls and windows, if present in the first representation, which are determined before (4) positions for load-bearing interior walls, if present within the first representation, which are determined before (5) interior non-load-bearing walls, if present within the first representation.

In a sixteenth aspect, in combination with one or more of the first aspect through the fifteenth aspect, the method further includes determining, based on the first representation, a type of the structure; and selecting the hierarchy from a plurality of hierarchies based on the type of the structure.

A seventeenth aspect provides a system that includes a processor; and a memory storing instructions which, when executed by the processor, cause the processor to perform operations. The operations may include receiving a first representation of a structure; determining a second representation of the structure by aligning positions of objects within the first representation according to a hierarchy; and outputting the second representation of the structure.

In an eighteenth aspect, in combination with the seventeenth aspect, aligning the positions of the objects within the first representation includes determining, based on the objects and initial positions for the objects, first updated positions for the objects.

In a nineteenth aspect, in combination with one or more of the seventeenth aspect through the eighteenth aspect, aligning the positions of the object further includes determining, based on the first updated positions for the objects, second updated positions for the objects.

A twentieth aspect provides a non-transitory, computer-readable medium storing instructions which, when executed by a processor, cause the processor to perform operations. The operations include receiving a first representation of a structure; determining a second representation of the structure by aligning positions of objects within the first representation according to a hierarchy; and outputting the second representation of the structure.

Additional or alternative implementations are discussed below. The second representation of the structure may be determined such that positions for objects located higher in the hierarchy take precedence over positions for objects located lower in the hierarchy. Aligning the positions of objects within the first representation may include determining, based on positions of a first subset of the objects, aligned positions of a second subset of the objects. The method may also include determining, based on the aligned positions of the second subset of the objects, aligned positions of a third subset of the objects. The method may also include, before determining aligned positions of the second subset of the objects, determining aligned positions of the first subset of the objects. The first representation may be received from a machine learning model. The method may also include training the machine learning model based on differences between the first representation of the structure and the second representation of the structure.

The features and advantages described herein are not all-inclusive and, in particular, many additional features and advantages will be apparent to one of ordinary skill in the art in view of the figures and description. Moreover, it should be noted that the language used in the specification has been principally selected for readability and instructional purposes, and not to limit the scope of the disclosed subject matter.

### BRIEF DESCRIPTION OF THE FIGURES

FIG. 1 illustrates a system for determining structural representations according to one aspect of the present disclosure.

FIGS. 2A-2D illustrate hierarchies according to aspects of the present disclosure.

FIG. 3 illustrates a method for determining structural representations according to one aspect of the present disclosure.

FIG. 4 illustrates a computing device according to one aspect of the present disclosure.

### DETAILED DESCRIPTION OF EXAMPLE EMBODIMENTS

Existing techniques for creating structural representations from architectural plans rely heavily on manual input and traditional CAD software, which are prone to errors and inefficiencies. Typically, architects create detailed plans which include structural elements, mechanical systems, and electrical systems. However, these plans often have inaccuracies stemming from manual drafting errors or inconsistencies across different versions of the plans. For example, errors in the placement of load-bearing walls or mechanical systems can propagate throughout a building, leading to structural instability or costly corrections during construction. Additionally, errors between the initial plans and the final structure can accrue due to adjustments or changes required during the construction process.

These inaccuracies can create significant problems in both maintaining existing buildings and planning subsequent modifications. Incorrectly documented structural elements may lead to miscalculations in load distribution, mechanical inefficiencies, or even safety hazards during maintenance or renovation. The traditional method of manually checking and correcting these errors post-construction is time-consuming, requires significant expertise, and is susceptible to human error.

One solution to this problem is to use machine learning models to detect and correct these inaccuracies. The present techniques involve multiple machine learning models configured to analyze and align architectural plans. The first model generates an initial layout, the second identifies and classifies objects within the layout, and the third aligns these objects according to a hierarchical structure. This hierarchical approach prioritizes load-bearing and central elements, ensuring that critical components are positioned accurately to reduce error propagation.

For example, structural grid objects like columns are aligned first, followed by structural core components such as elevator shafts, then exterior walls and windows, before finally addressing interior partitions. This approach minimizes inaccuracies and ensures that critical structural elements are precisely aligned, which significantly reduces the need for manual corrections.

In some aspects, the present disclosure provides techniques for automatically aligning structural representations that may be particularly beneficial in maintaining and updating plans for existing structures. For example, these techniques may reduce the time and effort required to create accurate, up-to-date building plans, thereby minimizing human error. In particular, aligning objects according to hierarchies in this manner can result in updated representations for structures that are more accurate than the original plans or representations for these buildings. By automating the alignment process, the system can improve the consistency and accuracy of structural elements in existing buildings, which is crucial for safe and efficient maintenance or future modifications.

Additionally, the updated positions generated by these techniques can be used to train other machine learning models, such as those that determine representations based on plan documents. By leveraging these corrected and accurate positions, the training data for these other models can be improved, resulting in better performance and accuracy in generating new structural representations. This iterative improvement can enhance the overall reliability and precision of automated architectural tools.

These advantages may also translate to an improved experience for end users, such as facility managers, architects, and construction managers, by providing them with tools that offer higher accuracy and efficiency in maintaining current building plans. Additionally, the automated corrections can be iteratively refined to meet stringent accuracy requirements, further enhancing the quality and reliability of the structural plans. By implementing these techniques, computing systems may improve processing efficiency, leading to cost savings and optimized resource utilization when updating plans for existing structures.

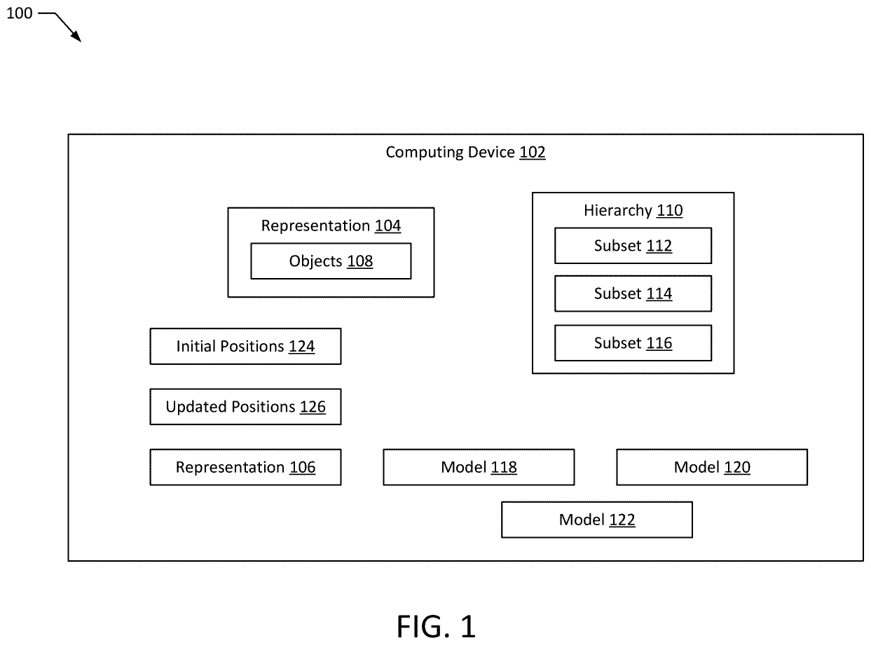

FIG. 1 illustrates a system 100 for determining structural representations according to one aspect of the present disclosure. The system 100 includes a computing device 102, which includes a first representation 104, an initial positions 124, an updated positions 126, a second representation 106, a hierarchy 110, a first machine learning model 118, a second machine learning model 120, and a third machine learning model 122. The first representation 104 includes an objects 108 and the hierarchy 110 includes a first subset 112 of the objects 108, a second subset 114 of the objects, and a third subset 116 of the objects.

The computing device 102 may be configured to receive a first representation 104 of a structure. In certain implementations, the first representation 104 may include a two-dimensional representation of the structure, three-dimensional representation of the structure, or a combination thereof. For example, the first representation 104 may be a three-dimensional model of the structure (such as an Autodesk Revit model, or other building information model (BIM) formats for the structure). As another example, the first representation 104 may be a blueprint or other drawing of a structure, such as a blueprint or other structural drawing prepared by an architect. In various aspect, the first representation 104 may represent an “as drawn” plan of the structure, an “as designed” plan of the structure, an “as built” plan of the structure, or combinations thereof. Two-dimensional representations may be stored in various formats, such as a Revit model, a PDF, vector image format, and the like. In certain implementations, the first representation 104 may be received from a model 118, such as a machine learning model. For example, the first representation 104 may be received from a machine learning model configured to determine building representations based on building plans. As specific examples, the model 118 may be one or more models implemented as described in U.S. application Ser. No. 17/487,838, entitled “Generating Vector Versions of Structural Plans”, U.S. application Ser. No. 17/559,297, entitled “Predicting Interior Models of Structures”, or combinations thereof. The specifications of both of these applications are incorporated by reference.

In certain implementations, structures may include buildings or other types of man-made structures. For example, the structure may include any structure with an interior space that is at least partially enclosed. As a specific example, the structure may include single-story buildings, multi-story building, warehouse structures, infrastructure facilities, outdoor structures (e.g., pavilions, gazebos, decks, bridges, dams), skyscrapers, wood frame residential buildings, concrete block commercial structures, light industrial buildings, big box retail buildings, bulk distribution buildings, or combinations thereof. As a further example, infrastructure facilities may include interior and exterior structures of dams, storm water pipes, sewer pipes, tunnels (e.g., access tunnels, tunnels for automobiles), channels, utility stations (e.g., pump stations), conduits (e.g., electrical conduits), and the like. Accordingly, any reference to structures herein should be understood to apply similarly to any type of structure.

The computing device 102 may be configured to determine a second representation 106 of the structure by aligning positions of objects 108 within the first representation 104 according to a hierarchy 110. In certain implementations, the second representation 106 of the structure may be determined to correct for one or more inaccuracies within the first representation 104 of the structure. In various implementations, the objects 108 may include objects 108 that define the structure or are otherwise included within the structure. In certain implementations, the objects 108 may include any physical object that may be depicted within the first representation 104 of the structure.

In certain implementations, the objects 108 may include structural components, which may include the physical parts that make up the structure of the building such as walls, floors, ceilings, and roofs. Example structural components may include reinforced concrete columns in a high-rise building or wooden beams in a residential house. In certain implementations, the objects 108 may include mechanical systems, which may include systems related to the mechanical aspects of a building including HVAC (heating, ventilation and air conditioning), plumbing and fire protection systems. Example mechanical systems may include ductwork layouts for an office building or piping layouts for an industrial plant. In certain implementations, the objects 108 may include electrical systems, which may include electrical installations within a structure that enable power distribution and lighting. Example electrical systems may include circuit components for residential homes or power distribution components for commercial buildings. In certain implementations, objects 108 may include landscaping elements, which may include the design and layout of outdoor spaces surrounding the structure including gardens, patios, driveways, and the like. Example landscaping elements may include garden designs for houses or parking lot designs for commercial buildings. In certain implementations, the objects 108 may include one or more material specifications, which may include detailed information about materials used in construction (such as the type, quality standards, application techniques, and the like). Example material specifications may include concrete specifications for foundations or glass specifications for windows. In certain implementations, the objects 108 may include furniture, such as placement of furniture within interior spaces or exterior spaces of the structure. Example furniture objects 108 may include office workstation arrangements or restaurant seating plans. In certain implementations, the objects 108 may include fixtures and fittings, which may include non-structural elements attached to buildings like light fixtures, cabinetry, and the like. In certain implementations, the objects 108 may include security systems, such as such as security camera placement.

In certain implementations, the computing device 102 may be further configured to determine indications of the objects 108 and initial positions 124 for the objects 108. In certain implementations, the first representation 104 of the structure may include indications of the objects 108 and the initial positions 124. In certain implementations, determining the objects 108 and the initial positions 124 of the objects 108 may include identifying indications of the objects 108 and the initial positions 124 within the first representation 104.

In certain implementations, the computing device 102 may be configured to determine the objects 108 and the initial positions 124 using a machine learning model, such as the second machine learning model 120. In additional or alternative implementations, the computing device 102 may be configured to determine indications of the objects 108 and the initial positions 124 based on the first representation 104, plan documents for the structure, or a combination thereof. In certain implementations, the plan documents may include one or more of the plans discussed above (e.g., a blueprint or other structural drawing of the structure). The plan documents may represent original copies (e.g., scanned copies of plans, original versions of plans). In certain aspect, the plan documents can include detailed plan sheets within a blueprint of the structure. In certain implementations, the indications of the objects 108 and the initial positions 124 are determined with a second machine learning model 120.

In certain implementations, the indications of the objects 108 include (i) a type for the objects 108, (ii) dimensions for the objects 108, (iii) compositions of the objects 108, (iv) a source location within plan documents for the structure, or a combination thereof. A type for the objects 108 may refer to the classification or category of the object within the structure. For instance, an HVAC unit may be categorized under mechanical systems, while a circuit breaker may be categorized under electrical systems. As another example, a concrete column would be listed as a structural component, and a garden design would be listed under landscaping elements. In certain instances, the type may identify both what kind of object (e.g., HVAC unit) and a classification for the object (e.g., mechanical systems). The dimensions for the objects 108 include specific measurements or sizes of the objects. For example, a concrete column might have dimensions of 24×24 inches, while an HVAC duct might have a diameter of 18 inches. As another example, a wooden beam in a house might be 10 feet long and 6 inches wide, and a window might be 4 feet wide and 5 feet tall. The compositions of the objects 108 refer to the material or materials that make up the objects. For example, a structural column may be composed of reinforced concrete, while interior walls could be constructed from gypsum board. Likewise, plumbing pipes might be made of copper or PVC, and exterior walls could be composed of masonry bricks, which may be determined based on the plans or based on typical conventions/code requirements. The source location within plan documents for the structure indicates the specific part of the architectural plans where information about the object can be found. For example, details about a steel frame might be found on sheet 42 of the plan documents. Similarly, HVAC layouts might be on page 21 within the section that covers building services.

In certain embodiments, the initial identification of objects may be determined based on annotations or patterns within plans. For example, hatch patterns in the plans may denote different materials such as concrete or steel, while specific annotations could provide additional context like dimensions and material compositions. The machine learning model 120 may be trained to recognize these visual indicators and accurately classify and locate corresponding structural elements. As another example, dimensions of walls indicated in the plans can help distinguish between various types of walls, such as load-bearing concrete block walls and non-load-bearing partition walls.

In particular, the hierarchy 110 may identify a first subset 112 of objects that has a first priority, a second subset 114 of objects that has a second priority, and a third subset 116 of objects that has a third priority. The hierarchy 110 may include additional subsets with additional priorities (not depicted). In certain implementations, the first priority may be higher than the second priority, and the second priority may be higher than the third priority. In certain implementations, the second representation 106 of the structure may be determined such that positions for objects 108 located higher in the hierarchy 110 take precedence over positions for objects 108 located lower in the hierarchy 110. For example, conflicts between positions of objects 108 may be resolved in favor of the positions indicated by features that are higher on the hierarchy 110. In certain implementations, positions for objects 108 that are lower on the hierarchy 110 and conflict with positions of objects 108 that are higher on the hierarchy 110 may then be determined to stay as close as possible to the originally-indicated positions in the first representation 104 (such as while continuing to comply with code requirements, etc.).

In certain implementations, the hierarchies may be determined based on the load-bearing functions of objects, centrality within the structure, the potential impact of errors in positioning, or a combination thereof. For instance, elements central to the structure like elevator shafts may be prioritized higher because errors in their placement can propagate in all directions, affecting accuracy of representations for the entire structure. Similarly, primary load-bearing elements like support columns may be given precedence to ensure overall structural stability and alignment between floors. By applying these principles, the hierarchy may effectively reduce potential inaccuracies and maintain the structural and functional integrity of the building throughout the alignment process.

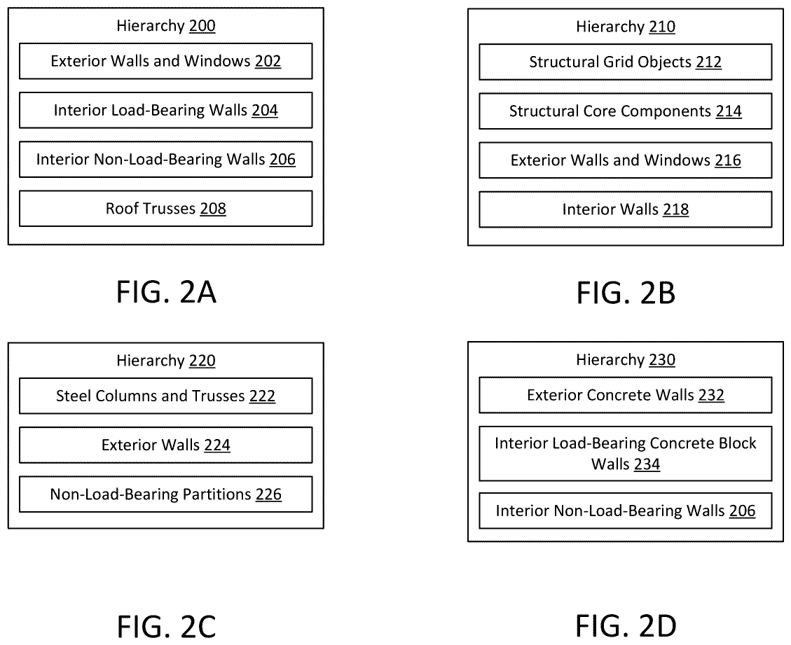

In one example hierarchy 110, (1) positions for structural grid objects 108 may be determined before (2) positions for structural core components, which may be determined before (3) positions for exterior walls and windows, which may be determined before (4) positions of interior walls. Structural grid objects 108 may include load-bearing portions of a structure, such as support columns and the like. Structural core objects 108 may include elevator shafts, electrical components, mechanical components, and the like. In certain implementations, structural core objects 108 may further include duct work, pluming, and restroom equipment. Additional hierarchies are discussed further below in connection with FIG. 2A-2D.

Structural grid objects may include load-bearing portions of a structure, such as support columns, floor slabs, and the like. Structural core objects may include elevator shafts, electrical components, mechanical components, and the like. In certain implementations, structural core objects may further include duct work, plumbing, and restroom equipment. Skyscrapers, for example, may be built with a structural grid that includes a stacked arrangement of columns and slabs. The structural grid may be the same or similar (such as may align) between floors of the building. Load-bearing walls may include interior walls that are load-bearing for a structure, but are not arranged as a structural grid (such as according to one or more industry standards, conventions, or combinations thereof). One skilled in the art will appreciate that there are many different arrangements of building components and systems that may constitute a structural grid for various buildings. Similarly, one skilled in the art will appreciate that there are many different arrangements of building components and systems that may constitute a structural core for various buildings. Additionally, one skilled in the art may understand that there are many different arrangements of building components and systems that may constitute load-bearing walls for various buildings. For example, one or more of the types of objects may be defined according to one or more relevant industry standards, conventions, or combinations thereof.

In certain implementations, the computing device 102 may store or otherwise have access to multiple hierarchies, which may each be associated with one or more types of structures. In such instances, the computing device may be configured to determine a type for the structure (e.g., based on the first representation 104). The computing device 102 may then select, retrieve, or otherwise access the hierarchy 110 based on the hierarchy 110. For example, the computing device 110 may determine that the first representation 110 indicates that the structure is a skyscraper and may select the hierarchy 110 as corresponding to the “skyscraper” structure type.

In certain implementations, aligning the positions of objects 108 within the first representation 104 include determining, based on positions of a first subset 112 of the objects 108, aligned positions of a second subset 114 of the objects 108. For example, when positions between one or more of the first subset 112 of the objects 108 conflict with positions for one or more of the second subset 114 of the objects 108, the positions of the first subset 112 may take precedence, and the positions of the second subset 114 may be adjusted to correct or otherwise resolve the conflict. In certain implementations, determining the second representation 106 may include determining, based on the aligned positions of the second subset 114 of the objects 108, aligned positions of a third subset 116 of the objects 108.

In certain implementations, aligning the positions of the objects 108 within the first representation 104 includes determining, based on the objects 108 and initial positions 124 for the objects 108, first updated positions 126 for the objects 108. In certain implementations, this involves taking the initial locations of the objects within the building plan and adjusting their positions to correct any inaccuracies. For example, if a wall is shown slightly out of alignment in the initial plan (e.g., based on determined positions for other objects), a position for the wall may be updated to correct for this discrepancy. In certain implementations, the updated positions 126 are further determined based on plan documents for the structure. In certain implementations, the plan documents may include one or more plans used to determine the first representation 104 as discussed above, such as initial layout plans and detailed architectural drawings.

In certain implementations, determining the first updated positions 126 includes determining a first subset of the first updated positions 126 for a first subset 112 of the objects 108 by aligning objects 108 of the first subset 112 of objects 108 across multiple floors of the structure. In certain implementations, positions of objects 108, such as the first subset 112 of objects 108, may be determined such that positions for objects 108 that extend between multiple floors of the structure are aligned. For example, positions of the structural grid may be determined to comply with positions indicated on multiple floors. In certain embodiments, this alignment process may correct the positions of vertical elements like support columns or elevator shafts for improved consistency between floors to more accurately reflect their positions within the structure.

In certain implementations, determining the first updated positions 126 may also include determining a second subset of the first updated positions 126 for a second subset 114 of the objects 108 (i) based on the first subset 112 of the first updated positions 126 and (ii) by aligning objects 108 of the second subset 114 of the objects 108 across multiple floors of the structure. For example, when positions between one or more of the first subset 112 of the objects 108 conflict with positions for one or more of the second subset 114 of the objects 108. In certain embodiments, this process involves resolving conflicts where secondary elements, such as mechanical rooms or utility shafts, intersect with primary structural elements like support columns, such as after positions for these objects are updated with the first subset of the first updated positions 126. For example, a mechanical room that spans multiple floors may need to be repositioned in the plan to accurately reflect its actual position and avoid conflicts with the corrected positions of vertical support columns.

In certain implementations, determining the first updated positions 126 includes determining a third subset of the first updated positions 126 for a third subset 116 of the objects 108 (i) based on the second subset 114 of the second updated positions 126 and (ii) by aligning objects 108 of the third subset 116 of the objects 108 across multiple floors of the structure. For example, determining the third subset of the first updated positions 126 may be performed using similar techniques for determining the second subset of the first updated positions 126 based on the first subset 112 of the first updated positions 126. For example, interior partition walls on multiple floors may be aligned to match the actual layout of mechanical and structural elements, such as based on conflicts with the first subset of the first updated positions 126, the second subset of the first updated positions 126, or a combination thereof.

In certain implementations, the process of determining the updated positions 126 for objects 108 to align positions of the objects 108 may be iterative and may be repeated multiple times to improve the accuracy. In certain embodiments, this iterative approach may involve repeatedly refining the positions of objects until the discrepancies between the actual and intended positions are minimized. Each iteration may use the output of the previous iteration as an input, ensuring that with each pass, the positions of the objects become more accurate and better aligned with the design specifications. This iterative process may help in achieving high precision and reducing errors in the alignment of objects within the structural plan. In particular, aligning the positions of the object further includes determining, based on the first updated positions 126 for the objects 108, second updated positions 126 for the objects 108.

In certain implementations, the process of determining the updated positions may be repeated until at least one condition is satisfied. For example, the computing device 102 may be further configured to determine that the second updated positions 126 for the objects 108 satisfy at least one condition and, in response, may use the second updated positions 126 within the second representation 106 of the structure. In certain implementations, the conditions may include criteria such as maximum allowable positional adjustments, minimum acceptable alignment accuracy, or a predefined number of iterations. For instance, the process might continue until the positional adjustments for all high-priority objects are below a certain threshold, such as 0.1 inches, 0.05 inches, 0.01 inches, 0.5 inches, and the like. As another example, a condition for minimum acceptable alignment accuracy might specify that the overall error for the updated positions 126 must be within 0.1% of the total structure dimensions, 0.01%, 0.001%, 0.0001%, 0.5%, and the like. Additionally, a predefined number of iterations might be used, such that the process will iterate a maximum number of times regardless of whether the other conditions are met sooner, such as 3 times, 5 times, 10 times, 25 times, 100 times, 1000 times, and the like. In certain embodiments, each positional adjustment made by the machine learning model may be associated with a confidence level, indicating the model's certainty regarding the adjustment. For instance, structural components such as columns and beams might have confidence levels above 95%, while non-structural partitions might have lower confidence levels. In such instances, a minimum confidence level may be required to stop determining updated positions, such as 95%, 99%, 90%, and the like for each position of each of at least a subset of the objects 108.

The computing device 102 may be configured to output the second representation 106 of the structure. In certain implementations, the second representation 106 may also be output to a user (such as an architect) for subsequent use. In certain implementations, the second representation 106 of the structure may be in the same or similar format as the first representation 104. For example, the second representation 106 may include a two-dimensional representation of the structure, a three-dimensional representation of the structure, or a combination thereof (such as in any of the above-discussed two-dimensional formats, three-dimensional formats).

In certain implementations, the second representation 106 may incorporate the final updated positions for objects within the structure. The computing device 102 may also output metadata about each object, such as its type, dimensions, material compositions, source location within the original plan documents, or a combination thereof. Additionally, the final representation may include annotations or flags indicating the confidence level of the alignments made and any potential areas where manual verification may be required (such as positions with a confidence below a predetermined threshold). The computing device may also determine and output a summary report highlighting the key adjustments made during the alignment process and referencing specific plan documents for traceability. For instance, if a structural column was repositioned by 0.1 inches, the summary report may document this change along with a reference to the original sheet where this column is depicted.

In certain implementations, the computing device 102 may output (e.g., based on output from the model) may also include a comprehensive list of all identified objects 108 within the structure, categorized and sorted based on their priority in the hierarchy 110. For example, the list may include structural grid components, structural core components, exterior walls and windows, and interior walls, each with their respective adjusted positions, dimensions, and materials. Each object may also be linked to its specific source and/or location(s) within the original plan documents, providing a clear traceability path for validation and audits.

Additionally, the computing device 102 may be configured to output indicators for any discrepancies or inconsistencies detected during the alignment process. For example, if an initial position deviated significantly from the updated, the system may flag this with an annotation explaining the nature and extent of the discrepancy. These flags may help architects and engineers identify areas that require closer inspection or manual adjustment.

In certain implementations, the second representation 106 may also be output to a user (such as an architect) for subsequent use. The second representation 106 of the structure may be in the same or similar format as the first representation 104. For example, the second representation 106 may include a two-dimensional representation of the structure, a three-dimensional representation of the structure, or a combination thereof (such as in any of the above-discussed two-dimensional formats, three-dimensional formats).

In certain implementations, the second representation 106, and any additional information discussed above, may be output via a graphical user interface (GUI). The GUI for the final representation may be designed to provide a clear, intuitive display of relevant information to the user. In certain implementations, the GUI may feature a multi-pane layout, allowing users to view the updated structural plan alongside the original plans. For example, one pane may display the adjusted positions of objects 108 within the structure, while an adjacent pane may show the original positions from the initial plan. This side-by-side comparison facilitates quick validation and verification by the user.

In certain embodiments, the GUI may include interactive elements such as clickable annotations or flags. Users can click on these annotations to view detailed information about specific changes, such as the type of object, its dimensions, material composition, and the source location within the original plan documents. For instance, clicking on a flagged structural column may bring up a pop-up window showing its original and adjusted positions, the rationale for the adjustment, and references to the specific plan sheets where it is documented.

The GUI may also feature a navigation panel that allows users to quickly jump between different sections of the structural plan. This panel may list all categories of objects 108 in the hierarchy 110, enabling users to filter and view specific types of objects, such as only structural core components or only exterior walls. This filtering capability may help users focus on the critical aspects of the structure and navigate the plan with ease.

Furthermore, the GUI may include a reporting function that generates a comprehensive summary report of all adjustments and alignments made by the model. This report may be exportable to various formats (e.g., PDF, Excel) and may include tables, charts, and diagrams that clearly illustrate the changes and their justifications. Users may be able to use this report for documentation purposes, compliance checks, and collaboration with other stakeholders.

By incorporating these features, the GUI not only enhances the transparency and verifiability of the final structural representation but also provides users with powerful tools for efficient and accurate building plan management.

The first machine learning model 118, second machine learning model 120, and third machine learning model 122 may be implemented as one or more machine learning models, including supervised learning models, unsupervised learning models, other types of machine learning models, and/or other types of predictive models. For example, the models 118, 120, 122 may be implemented as one or more of a neural network, a transformer model, a decision tree model, a support vector machine, a Bayesian network, a classifier model, a regression model, and the like. The models 118, 120, 122 may be trained based on training data to identify, classify, and align objects 108 within structural plans. For example, one or more training datasets may be used that contain labeled architectural plans, blueprints, 3D models, and their respective accurate representations. The training datasets may specify one or more expected outputs. For example, the expected output may be the correct positioning and categorization of structural elements such as walls, columns, and beams.

Parameters of the models 118, 120, 122 may be updated based on whether the models generate correct outputs when compared to the expected outputs. In particular, the models 118, 120, 122 may receive one or more pieces of input data from the training datasets that are associated with a plurality of expected outputs. The models may generate predicted outputs based on a current configuration of the models. The predicted outputs may be compared to the expected outputs and one or more parameter updates may be computed based on differences between the predicted outputs and the expected outputs. In particular, the parameters may include weights (e.g., priorities) for different features and combinations of features (e.g., object type, dimension, material composition, and source location within the plan documents). The parameter updates of the models 118, 120, 122 may include updating one or more of the features analyzed and/or the weights assigned to different features or combinations of features (e.g., relative to the current configuration of the models).

In certain implementations, one or more of the machine learning models 118, 120, 122 may be trained based on differences between the first representation 104 of the structure and the second representation 106 of the structure. For example, the third machine learning model 120 may be trained to adjust for, and remove bias (such as positional bias for certain components), for structural representations that are produced by the model 120. In this way, the disclosed techniques may enable improved training of one machine learning model for determining structural representations based on analysis of the representations by another machine learning model.

In certain implementations, separate models may be implemented by a single model to streamline processing and improve efficiency. For example, a single machine learning model may be configured to handle both determining the first representation 104 and identifying the objects 108. As another example, the initial positions 124 and the updated positions 126 may be determined by a single model. As a further example, identifying the objects 108, determining the initial positions 124, and determining the updated positions 126 may be determined by a single model.

FIGS. 2A-2D depict hierarchies according to exemplary aspects of the present disclosure. The hierarchies 200, 210, 220, 230 may depict hierarchies for use with different types of structures. For example, the hierarchy 200 may be used for residential buildings, the hierarchy 210 may be used for commercial office towers, the hierarchy 220 may be used for light industrial structures, and the hierarchy 230 may be used for concrete block structures.

Turning to FIG. 2A, in the hierarchy 200, (1) positions for exterior walls and windows 202 may be determined before (2) positions for interior load-bearing walls 204, which may be determined before (3) positions for interior non-load-bearing walls 206, which may be determined before (4) positions of roof trusses 208. This hierarchy ensures that the critical load-bearing components are positioned first to maintain structural integrity, followed by non-load-bearing elements that define internal spaces.

Turning to FIG. 2B, in the hierarchy 210, (1) positions for structural grid objects 212 may be determined before (2) positions for structural core components 214, which may be determined before (3) positions for exterior walls and windows 216, which may be determined before (4) positions of interior walls 218. This hierarchy is configured to prioritize the placement of critical load-bearing and service elements before addressing the building envelope and internal partitions, thereby ensuring overall structural stability and functionality.

Turning to FIG. 2C, in the hierarchy 220, (1) positions for steel columns and trusses 222 may be determined before (2) positions for exterior walls 224, which may be determined before (3) positions for non-load-bearing partitions 226. This hierarchy ensures that the robust structural framework is established first to support the roof and wide spans, followed by the building envelope, and finally the interior partitions.

Turning to FIG. 2D, in the hierarchy 230, (1) positions for exterior concrete block walls 232 may be determined before (2) positions for interior load-bearing concrete block walls 234, which may be determined before (3) positions for interior non-load-bearing walls 236. This hierarchy ensures that the fundamental load-bearing elements are set first for maximum structural stability, followed by internal divisions defining the building's layout.

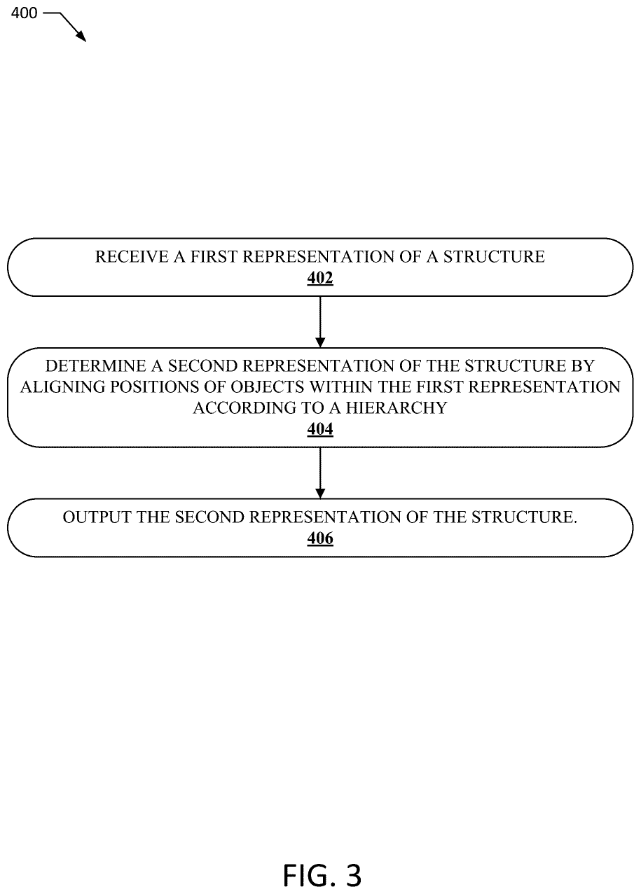

FIG. 3 illustrates a method 400 for determining structural representations according to one aspect of the present disclosure. The method 400 may be implemented on a computer system, such as the system 100. For example, the method 400 may be implemented by the computing device 102. The method 400 may also be implemented by a set of instructions stored on a computer readable medium that, when executed by a processor, cause the computing device to perform the method 400. Although the examples below are described with reference to the flowchart illustrated in FIG. 3, many other methods of performing the acts associated with FIG. 3 may be used. For example, the order of some of the blocks may be changed, certain blocks may be combined with other blocks, one or more of the blocks may be repeated, and some of the blocks may be optional.

The method 400 includes receiving a first representation of a structure (block 402). For example, the computing device 102 may receive a first representation 104 of a structure. In certain implementations, the first representation 104 may include a two-dimensional representation of the structure, three-dimensional representation of the structure, or a combination thereof.

The method 400 includes determining a second representation of the structure by aligning positions of objects within the first representation according to a hierarchy (block 404). For example, the computing device 102 may determine a second representation 106 of the structure by aligning positions of objects 108 within the first representation 104 according to a hierarchy 110. In certain implementations, the second representation 106 of the structure may be determined to correct for one or more inaccuracies within the first representation 104 of the structure. In various implementations, the objects 108 may include objects 108 that define the structure or are otherwise included within the structure. In certain implementations, the second representation 106 of the structure may be determined such that positions for objects 108 located higher in the hierarchy 110 take precedence over positions for objects 108 located lower in the hierarchy 110. In certain implementations, aligning the positions of objects 108 within the first representation 104 includes determining, based on positions of a first subset 112 of the objects 108, aligned positions of a second subset 114 of the objects 108. In certain implementations, aligning the positions of object 108 may further include determining, based on the aligned positions of the second subset 114 of the objects 108, aligned positions of a third subset 116 of the objects 108. In certain implementations, aligning the positions of the objects 108 may further include, before determining aligned positions of the second subset 114 of the objects 108, determining aligned positions of a first subset 112 of the objects 108.

The method 200 includes outputting the second representation of the structure (block 406). For example, the computing device 102 may output the second representation 106 of the structure. In certain implementations, the first representation 104 may be received from a model 118. In certain implementations, the method 200 further includes training the model 118 based on differences between the first representation 104 of the structure and the second representation 106 of the structure.

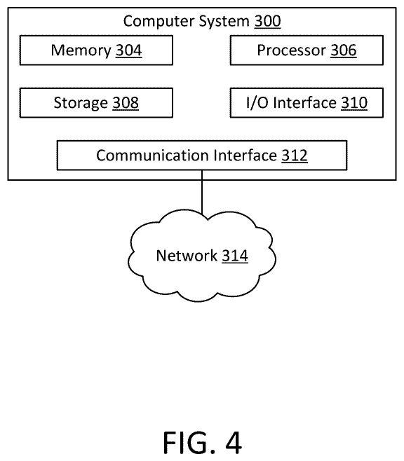

FIG. 4 illustrates a computer system 300 according to one aspect of the present disclosure. In particular, the computer system 300 may be utilized to implement one or more of the devices and/or components discussed herein, such as the computing device 102. In particular embodiments, one or more computer systems 300 perform one or more steps of one or more methods described or illustrated herein. In particular embodiments, one or more computer systems 300 provide the functionalities described or illustrated herein. In particular embodiments, software running on one or more computer systems 300 performs one or more steps of one or more methods described or illustrated herein or provides the functionalities described or illustrated herein. Particular embodiments include one or more portions of one or more computer systems 300. Herein, a reference to a computer system may encompass a computing device, and vice versa, where appropriate. Moreover, a reference to a computer system may encompass one or more computer systems, where appropriate.

This disclosure contemplates any suitable number of computer systems 300. This disclosure contemplates the computer system 300 taking any suitable physical form. As example and not by way of limitation, the computer system 300 may be an embedded computer system, a system-on-chip (SOC), a single-board computer system (SBC) (such as, for example, a computer-on-module (COM) or system-on-module (SOM)), a desktop computer system, a laptop or notebook computer system, an interactive kiosk, a mainframe, a mesh of computer systems, a mobile telephone, a personal digital assistant (PDA), a server, a tablet computer system, an augmented/virtual reality device, or a combination of two or more of these. Where appropriate, the computer system 300 may include one or more computer systems 300; be unitary or distributed; span multiple locations; span multiple machines; span multiple data centers; or reside in a cloud, which may include one or more cloud components in one or more networks. Where appropriate, one or more computer systems 300 may perform without substantial spatial or temporal limitation one or more steps of one or more methods described or illustrated herein. As an example, and not by way of limitation, one or more computer systems 300 may perform in real time or in batch mode one or more steps of one or more methods described or illustrated herein. One or more computer systems 300 may perform at different times or at different locations one or more steps of one or more methods described or illustrated herein, where appropriate.

In particular embodiments, computer system 300 includes a processor 306, memory 304, storage 308, an input/output (I/O) interface 310, and a communication interface 312. Although this disclosure describes and illustrates a particular computer system having a particular number of particular components in a particular arrangement, this disclosure contemplates any suitable computer system having any suitable number of any suitable components in any suitable arrangement.

In particular embodiments, the processor 306 includes hardware for executing instructions, such as those making up a computer program. As an example and not by way of limitation, to execute instructions, the processor 306 may retrieve (or fetch) the instructions from an internal register, an internal cache, memory 304, or storage 308; decode and execute the instructions; and then write one or more results to an internal register, internal cache, memory 304, or storage 308. In particular embodiments, the processor 306 may include one or more internal caches for data, instructions, or addresses. This disclosure contemplates the processor 306 including any suitable number of any suitable internal caches, where appropriate. As an example, and not by way of limitation, the processor 306 may include one or more instruction caches, one or more data caches, and one or more translation lookaside buffers (TLBs). Instructions in the instruction caches may be copies of instructions in memory 304 or storage 308, and the instruction caches may speed up retrieval of those instructions by the processor 306. Data in the data caches may be copies of data in memory 304 or storage 308 that are to be operated on by computer instructions; the results of previous instructions executed by the processor 306 that are accessible to subsequent instructions or for writing to memory 304 or storage 308; or any other suitable data. The data caches may speed up read or write operations by the processor 306. The TLBs may speed up virtual-address translation for the processor 306. In particular embodiments, processor 306 may include one or more internal registers for data, instructions, or addresses. This disclosure contemplates the processor 306 including any suitable number of any suitable internal registers, where appropriate. Where appropriate, the processor 306 may include one or more arithmetic logic units (ALUs), be a multi-core processor, or include one or more processors 306. Although this disclosure describes and illustrates a particular processor, this disclosure contemplates any suitable processor.

In particular embodiments, the memory 304 includes main memory for storing instructions for the processor 306 to execute or data for processor 306 to operate on. As an example, and not by way of limitation, computer system 300 may load instructions from storage 308 or another source (such as another computer system 300) to the memory 304. The processor 306 may then load the instructions from the memory 304 to an internal register or internal cache. To execute the instructions, the processor 306 may retrieve the instructions from the internal register or internal cache and decode them. During or after execution of the instructions, the processor 306 may write one or more results (which may be intermediate or final results) to the internal register or internal cache. The processor 306 may then write one or more of those results to the memory 304. In particular embodiments, the processor 306 executes only instructions in one or more internal registers or internal caches or in memory 304 (as opposed to storage 308 or elsewhere) and operates only on data in one or more internal registers or internal caches or in memory 304 (as opposed to storage 308 or elsewhere). One or more memory buses (which may each include an address bus and a data bus) may couple the processor 306 to the memory 304. The bus may include one or more memory buses, as described in further detail below. In particular embodiments, one or more memory management units (MMUs) reside between the processor 306 and memory 304 and facilitate accesses to the memory 304 requested by the processor 306. In particular embodiments, the memory 304 includes random access memory (RAM). This RAM may be volatile memory, where appropriate. Where appropriate, this RAM may be dynamic RAM (DRAM) or static RAM (SRAM). Moreover, where appropriate, this RAM may be single-ported or multi-ported RAM. This disclosure contemplates any suitable RAM. Memory 304 may include one or more memories 304, where appropriate. Although this disclosure describes and illustrates particular memory implementations, this disclosure contemplates any suitable memory implementation.

In particular embodiments, the storage 308 includes mass storage for data or instructions. As an example, and not by way of limitation, the storage 308 may include a hard disk drive (HDD), a floppy disk drive, flash memory, an optical disc, a magneto-optical disc, magnetic tape, or a Universal Serial Bus (USB) drive or a combination of two or more of these. The storage 308 may include removable or non-removable (or fixed) media, where appropriate. The storage 308 may be internal or external to computer system 300, where appropriate. In particular embodiments, the storage 308 is non-volatile, solid-state memory. In particular embodiments, the storage 308 includes read-only memory (ROM). Where appropriate, this ROM may be mask-programmed ROM, programmable ROM (PROM), erasable PROM (EPROM), electrically erasable PROM (EEPROM), electrically alterable ROM (EAROM), or flash memory or a combination of two or more of these. This disclosure contemplates mass storage 308 taking any suitable physical form. The storage 308 may include one or more storage control units facilitating communication between processor 306 and storage 308, where appropriate. Where appropriate, the storage 308 may include one or more storages 308. Although this disclosure describes and illustrates particular storage, this disclosure contemplates any suitable storage.

In particular embodiments, the I/O Interface 310 includes hardware, software, or both, providing one or more interfaces for communication between computer system 300 and one or more I/O devices. The computer system 300 may include one or more of these I/O devices, where appropriate. One or more of these I/O devices may enable communication between a person (i.e., a user) and computer system 300. As an example and not by way of limitation, an I/O device may include a keyboard, keypad, microphone, monitor, screen, display panel, mouse, printer, scanner, speaker, still camera, stylus, tablet, touch screen, trackball, video camera, another suitable I/O device or a combination of two or more of these. An I/O device may include one or more sensors. Where appropriate, the I/O Interface 310 may include one or more device or software drivers enabling processor 306 to drive one or more of these I/O devices. The I/O interface 310 may include one or more I/O interfaces 310, where appropriate. Although this disclosure describes and illustrates a particular I/O interface, this disclosure contemplates any suitable I/O interface or combination of I/O interfaces.

In particular embodiments, communication interface 312 includes hardware, software, or both providing one or more interfaces for communication (such as, for example, packet-based communication) between computer system 300 and one or more other computer systems 300 or one or more networks 314. As an example, and not by way of limitation, communication interface 312 may include a network interface controller (NIC) or network adapter for communicating with an Ethernet or any other wire-based network or a wireless NIC (WNIC) or wireless adapter for communicating with a wireless network, such as a Wi-Fi network. This disclosure contemplates any suitable network 314 and any suitable communication interface 312 for the network 314. As an example, and not by way of limitation, the network 314 may include one or more of an ad hoc network, a personal area network (PAN), a local area network (LAN), a wide area network (WAN), a metropolitan area network (MAN), or one or more portions of the Internet or a combination of two or more of these. One or more portions of one or more of these networks may be wired or wireless. As an example, computer system 300 may communicate with a wireless PAN (WPAN) (such as, for example, a Bluetooth® WPAN), a WI-FI network, a WI-MAX network, a cellular telephone network (such as, for example, a Global System for Mobile Communications (GSM) network), or any other suitable wireless network or a combination of two or more of these. Computer system 300 may include any suitable communication interface 312 for any of these networks, where appropriate. Communication interface 312 may include one or more communication interfaces 312, where appropriate. Although this disclosure describes and illustrates a particular communication interface implementations, this disclosure contemplates any suitable communication interface implementation.

The computer system 302 may also include a bus. The bus may include hardware, software, or both and may communicatively couple the components of the computer system 300 to each other. As an example and not by way of limitation, the bus may include an Accelerated Graphics Port (AGP) or any other graphics bus, an Enhanced Industry Standard Architecture (EISA) bus, a front-side bus (FSB), a HYPERTRANSPORT (HT) interconnect, an Industry Standard Architecture (ISA) bus, an INFINIBAND interconnect, a low-PIN-count (LPC) bus, a memory bus, a Micro Channel Architecture (MCA) bus, a Peripheral Component Interconnect (PCI) bus, a PCI-Express (PCIe) bus, a serial advanced technology attachment (SATA) bus, a Video Electronics Standards Association local bus (VLB), or another suitable bus or a combination of two or more of these buses. The bus may include one or more buses, where appropriate. Although this disclosure describes and illustrates a particular bus, this disclosure contemplates any suitable bus or interconnect.

Herein, a computer-readable non-transitory storage medium or media may include one or more semiconductor-based or other types of integrated circuits (ICs) (e.g., field-programmable gate arrays (FPGAs) or application-specific ICs (ASICs)), hard disk drives (HDDs), hybrid hard drives (HHDs), optical discs, optical disc drives (ODDs), magneto-optical discs, magneto-optical drives, floppy diskettes, floppy disk drives (FDDs), magnetic tapes, solid-state drives (SSDs), RAM-drives, SECURE DIGITAL cards or drives, any other suitable computer-readable non-transitory storage media, or any suitable combination of two or more of these, where appropriate. A computer-readable non-transitory storage medium may be volatile, non-volatile, or a combination of volatile and non-volatile, where appropriate.

Herein, “or” is inclusive and not exclusive, unless expressly indicated otherwise or indicated otherwise by context. Therefore, herein, “A or B” means “A, B, or both,” unless expressly indicated otherwise or indicated otherwise by context. Moreover, “and” is both joint and several, unless expressly indicated otherwise or indicated otherwise by context. Therefore, herein, “A and B” means “A and B, jointly or severally,” unless expressly indicated otherwise or indicated otherwise by context.

The scope of this disclosure encompasses all changes, substitutions, variations, alterations, and modifications to the example embodiments described or illustrated herein that a person having ordinary skill in the art would comprehend. The scope of this disclosure is not limited to the example embodiments described or illustrated herein. Moreover, although this disclosure describes and illustrates respective embodiments herein as including particular components, elements, features, functions, operations, or steps, any of these embodiments may include any combination or permutation of any of the components, elements, features, functions, operations, or steps described or illustrated anywhere herein that a person having ordinary skill in the art would comprehend. Furthermore, reference in the appended claims to an apparatus or system or a component of an apparatus or system being adapted to, arranged to, capable of, configured to, enabled to, operable to, or operative to perform a particular function encompasses that apparatus, system, component, whether or not it or that particular function is activated, turned on, or unlocked, as long as that apparatus, system, or component is so adapted, arranged, capable, configured, enabled, operable, or operative. Additionally, although this disclosure describes or illustrates particular embodiments as providing particular advantages, particular embodiments may provide none, some, or all of these advantages.

All of the disclosed methods and procedures described in this disclosure can be implemented using one or more computer programs or components. These components may be provided as a series of computer instructions on any conventional computer readable medium or machine readable medium, including volatile and non-volatile memory, such as RAM, ROM, flash memory, magnetic or optical disks, optical memory, or other storage media. The instructions may be provided as software or firmware and may be implemented in whole or in part in hardware components such as ASICs, FPGAs, DSPs, or any other similar devices. The instructions may be configured to be executed by one or more processors, which when executing the series of computer instructions, performs or facilitates the performance of all or part of the disclosed methods and procedures.

It should be understood that various changes and modifications to the examples described here will be apparent to those skilled in the art. Such changes and modifications can be made without departing from the spirit and scope of the present subject matter and without diminishing its intended advantages. It is therefore intended that such changes and modifications be covered by the appended claims.

1. A method comprising:
receiving a first representation of a structure;
determining a second representation of the structure by aligning positions of objects within the first representation according to a hierarchy; and
outputting the second representation of the structure.

2. The method of claim 1, wherein the first representation is received from a machine learning model.

3. The method of claim 2, further comprising training the machine learning model based on differences between the first representation of the structure and the second representation of the structure.

4. The method of claim 1, further comprising determining indications of the objects and initial positions for the objects.

5. The method of claim 4, further comprising determining indications of the objects and the initial positions based on the first representation, plan documents for the structure, or a combination thereof.

6. The method of claim 5, wherein the indications of the objects and the initial positions are determined with a second machine learning model.

7. The method of claim 4, wherein the indications of the objects include (i) a type for the objects, (ii) dimensions for the objects, (iii) compositions of the objects, (iv) a source location within plan documents for the structure, or a combination thereof.

8. The method of claim 1, wherein the second representation of the structure is determined such that positions for objects located higher in the hierarchy take precedence over positions for objects located lower in the hierarchy.

9. The method of claim 1, wherein aligning the positions of the objects within the first representation comprises determining, based on the objects and initial positions for the objects, first updated positions for the objects.

10. The method of claim 9, wherein the updated positions are determined with a third machine learning model.

11. The method of claim 9, wherein determining the first updated positions comprises determining a first subset of the first updated positions for a first subset of the objects by aligning objects of the first subset of objects across multiple floors of the structure.

12. The method of claim 11, wherein determining the first updated positions comprises determining a third subset of the third updated positions for a third subset of the objects (i) based on the second subset of the second updated positions and (ii) by aligning objects of the third subset of the objects across multiple floors of the structure.

13. The method of claim 9, wherein aligning the positions of the object further comprises determining, based on the first updated positions for the objects, second updated positions for the objects.

14. The method of claim 13, further comprising:
determining that the second updated positions for the objects satisfy at least one condition; and
using the second updated positions within the second representation of the structure.

15. The method of claim 1, wherein the hierarchy specifies that (1) positions for structural grid objects are determined, if present in the first representation, before (2) positions for structural core objects, if present in the first representation, which are determined before (3) exterior walls and windows, if present in the first representation, which are determined before (4) positions for load-bearing interior walls, if present within the first representation, which are determined before (5) interior non-load-bearing walls, if present within the first representation.

16. The method of claim 1, further comprising:
determining, based on the first representation, a type of the structure; and
selecting the hierarchy from a plurality of hierarchies based on the type of the structure.

17. A system comprising:
a processor; and
a memory storing instructions which, when executed by the processor, cause the processor to perform operations including:
receiving a first representation of a structure;
determining a second representation of the structure by aligning positions of objects within the first representation according to a hierarchy; and
outputting the second representation of the structure.

18. The system of claim 17, wherein aligning the positions of the objects within the first representation comprises determining, based on the objects and initial positions for the objects, first updated positions for the objects.

19. The system of claim 18, wherein aligning the positions of the object further comprises determining, based on the first updated positions for the objects, second updated positions for the objects.

20. A non-transitory, computer-readable medium storing instructions which, when executed by a processor, cause the processor to perform operations, comprising:
receiving a first representation of a structure;
determining a second representation of the structure by aligning positions of objects within the first representation according to a hierarchy; and
outputting the second representation of the structure.
